(19) United States
(12) Patent Application Publication
(10) Pub. No.: US 2006/0273310 A1
(43) Pub. Date: Dec. 7, 2006

(54) Light-Emitting Component with an Arrangement of Electrodes

(75) Inventors: Jan Birnstock, Dresden (DE); Sven Murano, Dresden (DE)

Correspondence Address: SUTHERLAND ASBILL & BRENNAN LLP, 999 PEACHTREE STREET, N.E., ATLANTA, GA, 30309, US

(73) Assignee: NOVALED AG, Dresden (DE)

(21) Appl. No.: 11/421,249

(22) Filed: May 31, 2006

(30) Foreign Application Priority Data
Jun. 1, 2005 (EP) 050 11 772.0

(51) Int. Cl. H01L 29/08

(52) U.S. Cl. 257/40

(57) ABSTRACT

The invention concerns a light-emitting component with an arrangement of electrodes for applying an electrical voltage to multiple organic areas, which form a light-emitting area, are distributed across a component surface and which each emit light when the electrical voltage is applied, in which the multiple organic areas are arranged between a flat-formed electrode and a flat-formed counter-electrode, where the electrode consists of a part electrode and an additional part electrode, which is electrically isolated from the part electrode and is formed so that it interlocks with it, where the electrode and the counter-electrode are formed so that they do not overlap outside the light-emitting area when looking towards the component surface.

The invention concerns a light-emitting component with an arrangement of electrodes for applying an electric current to multiple organic areas, which form a light-emitting area, are distributed across a component surface and which each emit light when the electric current is applied, and in which the multiple organic areas are arranged between a flat-formed electrode and a flat-formed counter-electrode.

### BACKGROUND TO THE INVENTION

Document DE 101 45 492 A1 describes a light-emitting component with a light-emitting organic area, which produces white light by means of OLED (OLED—organic light-emitting diode) substructures, for example, in the form of flat-formed points or strips, which generate white light on different wavelengths, and by means of an adjacent diffuser. The OLED substructures are contacted by using separate electrodes and actuated by means of a voltage source, by which means an optimised mixture of the different colours may be achieved.

A procedure for manufacturing such a light-emitting component necessarily requires process stages, for example masking stages, to make possible the deposition of different materials on the substructure of the substrate. In addition, the structure of the substrate may be more complex than is the case with common white OLEDs, which emit white light directly. Nevertheless, the approach to generating white light on the basis of mixing light radiated from the substructures, which emit light on different wavelengths, has a significant advantage, namely the possibility of setting an aggregate mixed colour for the light emitted by means of a deliberate variation in the voltage or current supplied to the OLED substructures.

Should, for example, white light be produced by using red, green and blue OLED substructures, all the colour coordinates located within the triangle, which are covered by the individual colours on the CIE colour chart are fundamentally obtainable. If light from two different OLED substructures is mixed, e.g. from substructures, which emit yellow and blue light, all the points located on a line between the individual colour dots are accessible. Such a straight line ideally runs largely parallel to the curve of a black emitter, allowing the colour temperature to be set across a wide area. Such a possibility is particularly desirable for applications in the field of lighting technology, as it makes it possible for the user to adjust the light source individually, according to his wishes.

However, a disadvantage of such OLED-based white light generation is that the use of OLED substructures entails increased production costs compared to other OLED lighting designs, which dispense with additional structuring in the production of OLED illumination. This is disadvantageous to the commercial use of such lighting components.

As well as the aforementioned costs of additional structuring of the substrate and the additional process stages, it is also necessary to address the individual colours and thus the corresponding substructures. In this connection, the state of the art anticipates that an electrode used for actuation in OLED components be structured, for example, in the form of transparent ITO strips, which are then connected individually to a driver, similar to the case for a passive matrix display element. However, such an approach requires a connecting step for bonding during manufacture, for example by means of adhesive. This is usually a light-precision process, using, for example, alignment under a microscope. High temperatures are also usually required for bonding.

The use of a common connection for OLED substructures of the same type, which are formed in strips and emit light on the same wavelength, whilst different types of strip are connected separately, is therefore proposed in documents DE 199 16 745 A1 and DE 101 45 492 A1. Provision may be made for structuring the strip structure of the OLED substructures appropriately to actuate the electrodes used.

An organic light-emitting component is also described in the document US 2002/0084993 A1 in which organic areas in strip form, located between two electrodes, are connected to electrode sections in strip form through which an electrical voltage is applied to actuate the organic areas. Different voltages are applied to electrode sections in strip form in order to actuate the respective corresponding organic area.

A visual display unit based on light-emitting components is described in document EP 1 018 718 A1, in which multiple organic areas are arranged between a flat-formed electrode and a flat-formed counter-electrode, which emit light in three different colours when a voltage is applied to the electrode and counter-electrode, as is usual for visual display units.

Outside the area of the component formed by the multiple organic areas, parts of the electrode and counter-electrode are permanently electrically isolated by layers of insulation.

### SUMMARY OF THE INVENTION

The invention is based on the problem of creating a light-emitting component with an electrode arrangement for actuating multiple organic areas, each of which emits light when an electrical voltage is applied to the electrode arrangement, where it should be possible to manufacture the electrode arrangement in as few process stages and in as little space as possible.

This problem is solved according to the invention by a light-emitting component according to independent claims 1 and 16. Advantageous embodiments of the invention form the subject of dependent sub-claims.

According to one aspect of the invention a light-emitting component is provided with an electrode arrangement for the application of an electrical voltage to multiple organic areas, which form a light-emitting area and are distributed across a component surface and which each emit light when the electric current is applied, in which the multiple organic areas are arranged between a flat-formed electrode and a flat-formed counter-electrode, where the electrode consists of a par electrode and an additional part electrode, which is electrically isolated from the part electrode and formed to interlock with it, where the electrode and counter-electrode are formed so that they do not overlap each other outside the light-emitting area when looking towards the component surface.

According to the invention, outside the light-emitting area a non-overlapping configuration of the electrode and counter-electrode is provided.

Another aspect of the invention is the creation of a light-emitting component with an electrode arrangement for applying an electrical voltage to multiple organic areas, which are arranged between a flat-formed electrode and a flat-formed counter electrode of the electrode arrangement and each of which emits light when the electrical voltage is applied, where an arrangement of multiple series circuits of light-emitting organic components is formed, in which
the electrode is formed of multiple strip segments, which are arranged adjacent to each other, and the counter-electrode is segmented;
the multiple organic areas are each connected to one of the multiple strip segments of the electrode; and
the organic areas are each connected by the segmented counter-electrode to an adjacent strip segment, which is arranged adjacent to one of the multiple strip segments, so that one part of the multiple organic areas is connected to an adjacent strip segment on one side and another part of the organic areas is connected to an adjacent strip segment on the opposite side.

A major advantage which the invention achieves over the state of the art is that the manufacture of components with organic light-emitting substructures for generating light in different colours is significantly simplified. The yield can also be increased. These advantages entail a reduction in manufacturing costs. Electrical contacting is also simplified. Process stages can be waived, saving costs. In particular, unlike the state of the art, the process stage for producing one or more layers of insulation between the electrode and the counter-electrode can be waived.

In a practical further development of the invention, the counter-electrode has a part counter-electrode and an additional pan counter-electrode, which is electrically isolated from the part counter-electrode and interlocks with its and that the part electrode and the additional part electrode, and the part counter-electrode and additional part counter-electrode, are each arranged opposite each other when looking towards the component surface.

An advantageous embodiment of the invention, the part electrode and the additional part counter-electrode are each in contact with two different organic areas out of the multiple organic areas.

A further development of the invention preferably provides for the two different organic areas to be formed so that they emit light of different colours.

A preferred advanced development of the invention can provide for the part electrode and the additional part counter-electrode being formed so that they overlap, at least partially, within the light-emitting area when looking towards the component surface.

A practical further development of the invention provides for the additional part electrode and the part counter-electrode each being in contact with precisely one of the organic areas.

An advantageous embodiment of the invention provides for precisely one organic area to emit light which is different from the light which is emitted from the two different organic areas.

A further development of the invention preferably provides for electrode sections of the part electrode and electrode sections of the additional part electrode being arranged offset when looking towards the component surface having a gap in between.

A preferred advanced development of the invention may provide for, in the counter-electrode, electrode sections of the part counter-electrode and electrode sections of the additional part counter-electrode being arranged offset to one another having a gap in between when looking towards the component surface.

A practical further development of the invention provides for the electrode and/or the counter-electrode having electrode sections in the form of a strip.

An advantageous embodiment of the invention provides that the electrode and/or the counter-electrode are each formed in a single layer.

A further development of the invention provides for the electrode and/or counter-electrode being distributed over multiple layers.

A preferred advanced embodiment of the invention may provide that the electrode and/or counter-electrode are formed so that they largely overlap the organic areas within the light-emitting area.

A practical further development of the invention provides for the part electrode and the additional part electrode, and the part counter-electrode and additional part counter-electrode, interlocking with each other in the form of a comb.

An advantageous embodiment of the invention provides for the multiple organic areas to have an aggregate white light emission spectrum.

### DESCRIPTION OF PREFERRED EMBODIMENT EXAMPLES OF THE INVENTION

The invention is explained in more detail below by means of embodiment examples, with reference to the drawings, wherein:

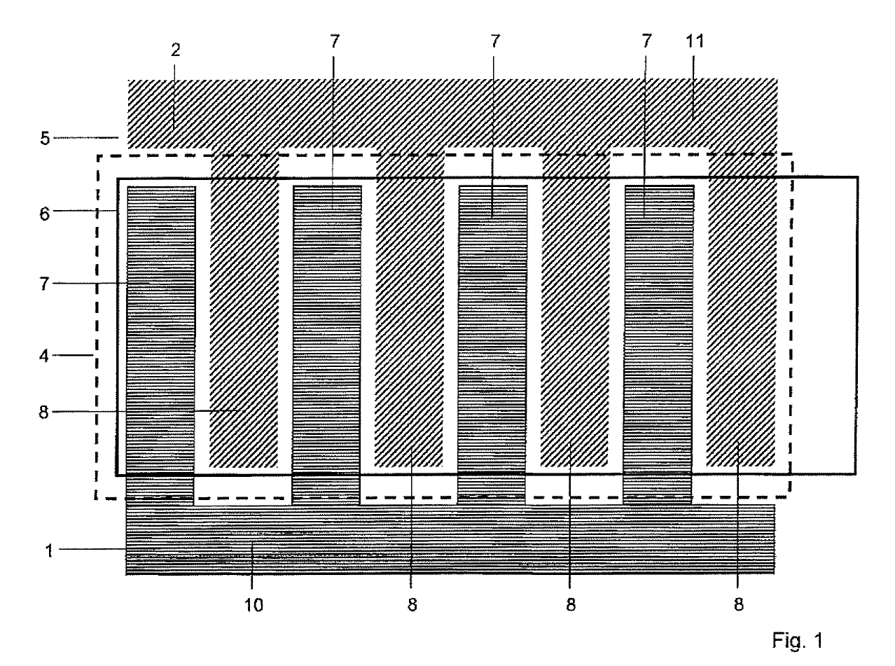

FIG. 1 is a schematic representation of a light-emitting component with multiple organic areas, which are distributed across a component surface and which each emit light in two different colours when an electrical voltage is applied, where part electrodes of the electrode are formed so that they do not overlap when looking towards the component surface;

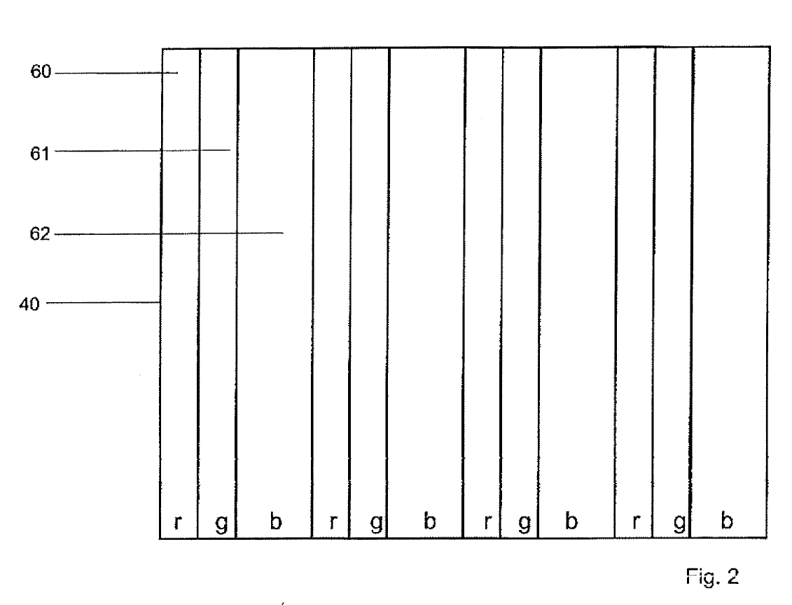

FIG. 2 is a schematic representation of an arrangement of multiple organic areas for a light-emitting component;

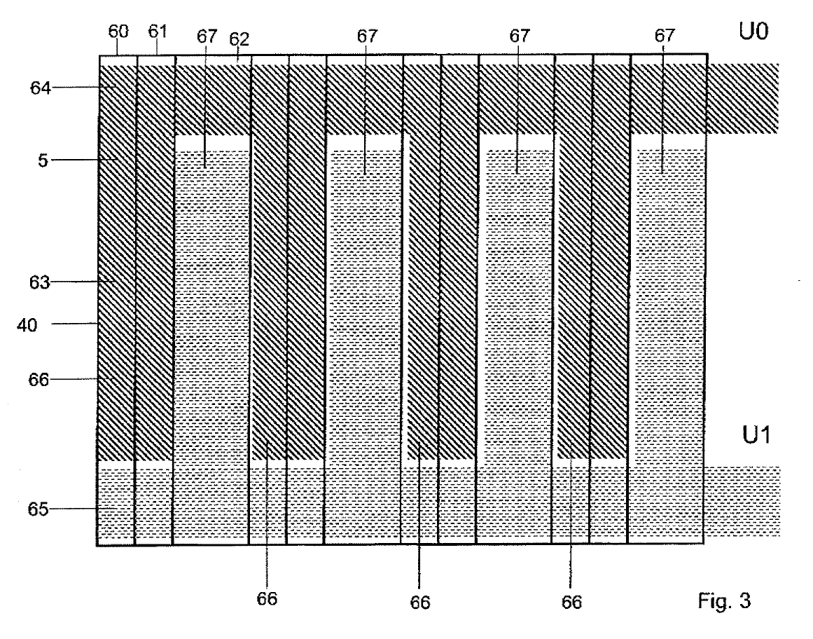

FIG. 3 is a schematic representation of the arrangement of multiple organic areas according to FIG. 2, where a lower electrode is formed with two non-overlapping part electrodes;

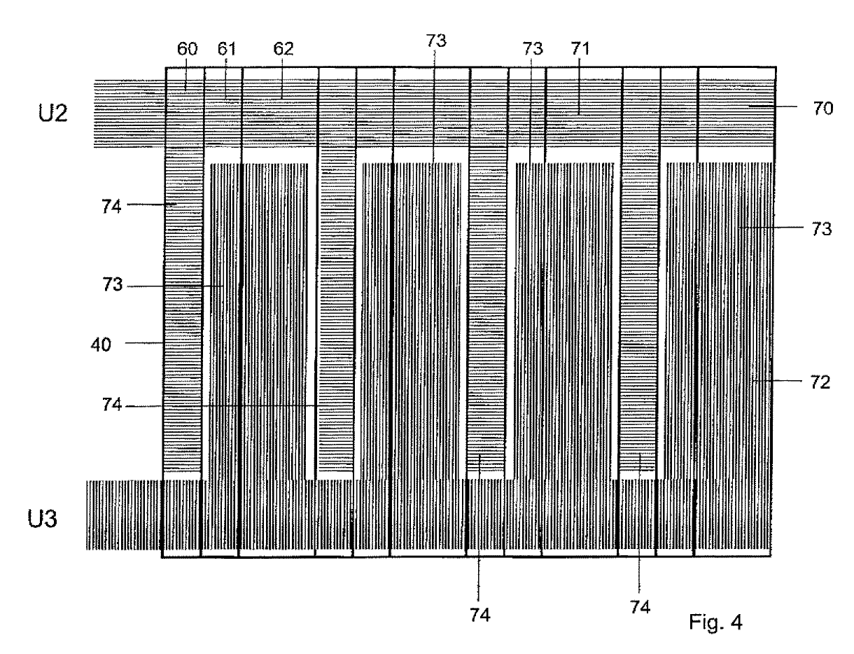

FIG. 4 is a schematic representation of the arrangement of multiple organic areas according to FIG. 2, where an upper electrode with two non-overlapping part electrodes is formed; and

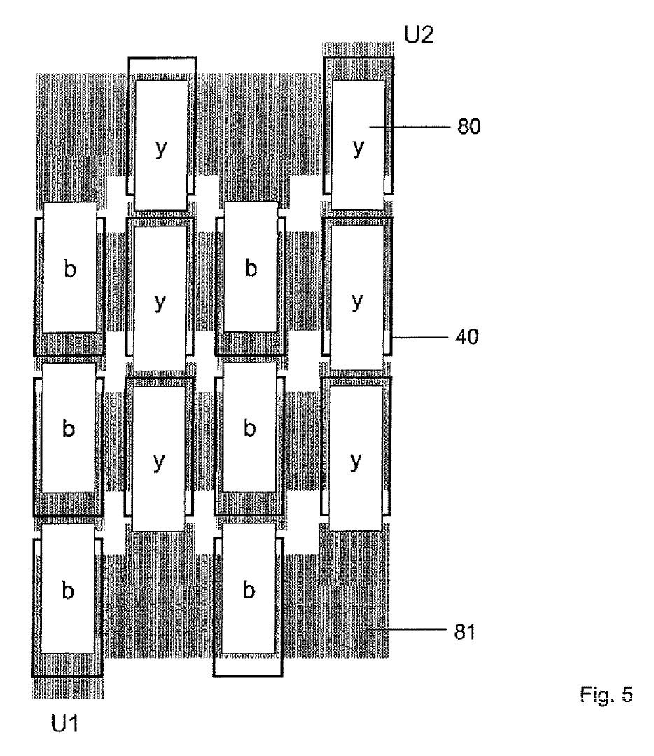

FIG. 5 is a schematic representation of an electrode arrangement and multiple organic areas for a light-emitting component, where an arrangement with multiple series circuits of organic light-emitting components is formed.

FIG. 1 is a schematic representation of an electrode for a light-emitting component in which light-emitting organic areas are actuated through the electrode, by the application of an electrical voltage. The electrode includes two flat-formed part electrodes 1, 2, which are formed in layers adjacent to each other. Above the two part electrodes 1, 2, a light-emitting area 4 is formed as a layer, which has multiple organic layers, which are themselves distributed across a component surface 5 and which emit light when an electrical voltage is applied. In the embodiment shown, the light-emitting area 4 comprises two organic areas with different structures, each of which emits light in a certain colour. A flat-formed counter-electrode 6 is arranged above the light-emitting area 4.

By applying an electrical voltage to the electrode, which comprises the part electrodes 1, 2 and the counter-electrode 6, an electrical voltage is applied to the multiple organic areas in the light-emitting area 4, so that light is emitted. Two different organic areas are formed, which differ in their material composition so that they emit light in different colours.

Electrode sections 7, 8 are each provided on both part electrodes 1, 2, which are formed on a connecting section 10, 11 comprised in the respective part electrode 1, 2 and which are arranged offset when looking towards the component surface having a gap in between. The electrode sections 7 of part electrode 1 are connected by one type of organic area which emits light in a first colour. The electrode sections 8 of part electrode 2 are connected by a second type of organic area, which emits light in a second colour. According to FIG. 1, pall electrodes 1, 2 do not overlap when looking towards the component surface 5.

According to FIG. 1, the two part electrodes 1, 2 are not formed so that they overlap when looking towards the component surface 5. This makes it possible to form the part electrodes 1, 2 in two separate layers or alternatively in one common layer during manufacture. The electrode sections 7, 8 mutually interlock in the comb-formed part electrodes 1, 2. This supports the space-saving embodiment of part electrodes 1, 2. Above the part electrodes 1, 2, the organic areas of different types may be actuated separately to emit light.

In addition, it emerges from FIG. 1 that the electrode consisting of the two part electrodes 1, 2 and the counter-electrode 6 do not overlap outside the light-emitting area 4 when looking towards the component surface 5. It is therefore not necessary to provide one or more layers of insulation between the electrodes.

It is also possible to form a light-emitting component, for example in strip form, free of insulation layers, which, unlike the embodiment according to FIG. 1, has more than two different types of organic area, as is known from the state of the art. FIGS. 2 to 4 show such an embodiment. FIG. 2 shows a schematic representation of an arrangement of three organic areas 60, 61, 62, which form a light-emitting area 40, comparable to the light-emitting area 4 in FIG. 1. In this case, the embodiment example shown involves organic areas, which emit red, green and blue light.

According to FIG. 3, an arrangement of two lower part electrodes 64, 65 is formed as flat-formed lower electrode 63, in which the strip-formed electrode sections 66, 67 are arranged so that they interlock and are offset when looking towards the component surface having a gap in between. In this case, provision is made for the electrode sections 66 of the lower part electrode 64 to extend across two organic areas 60, 61 and be electrically connected to them, where a basic surface of the electrode sections 66 overlaps the basic area of the organic areas 60, 61, at least in partial areas. Operating voltages U0 and U1 are applied to the lower part electrodes 64, 65 according to FIG. 3.

FIG. 4 is a schematic drawing of the arrangement of multiple organic areas according to FIG. 2, where a flat-formed upper electrode 70 is formed with two non-overlapping part electrodes 71, 72. Electrode sections 73 of the upper part electrode 72 are connected to the two organic areas 61, 62, whereas strip-formed electrode sections 74 of the upper part electrode 71 are electrically connected to the organic areas 60. Operating voltages U2 and U3 are applied to the upper part electrodes 71, 72 in accordance with FIG. 4.

Using the electrode layout according to FIGS. 3 and 4 in the arrangement of organic areas according to FIG. 2 ensures that the same voltage is applied to all the organic areas of the same type, whilst the operating voltages for the three different types of organic area differ. An operating voltage of U0-U2 is applied to all organic areas 60. In contrast, all organic areas 62 are supplied with operating voltage U1-U3. Finally, an operating voltage of U0-U3 is applied to organic areas 61.

By using the same design principle as explained in connection with FIGS. 2 to 4, an electrode arrangement for supplying voltage to a light-emitting area with four different types of organic area may also be formed, without an insulating layer in the area of the upper aid/or lower electrode being required to isolate part electrodes. In such an embodiment, each electrode section of the part electrodes in the upper and lower electrodes is electrically connected to two different types of organic area respectively. For example, the following operating voltages may be used to supply the different organic areas with different operating voltages, where the same operating voltage is applied to organic areas of the same type: U0-U2, U0-U3, U1-U2 and U1-U3. All four operating voltages may be selected freely and independently of each other.

In the embodiment examples in FIGS. 1 to 4, the organic areas to be actuated are strip-formed. The corresponding electrode sections are therefore also formed as strips. The design principles explained for forming the flat-formed electrodes can, however, be transferred to light-emitting components with organic areas formed in other ways, e.g. for organic areas, which have a round basic surface or are formed as zigzag lines. A space-saving electrode arrangement can also be produced at low cost in such components by using the invention.

FIG. 5 shows a schematic representation of an electrode arrangement and multiple organic areas for a light-emitting component, in which an arrangement with multiple series circuits of organic light-emitting components is formed. Even such a complicated arrangement can be achieved without the additional application of a layer of insulation for insolating part electrodes by using the design principles described above, FIG. 5 shows two different types of organic area, “b” and “y”, which emit light in two different colours. An upper electrode 80 and a lower electrode 81 are formed, between which the organic light-emitting areas are arranged. The two voltages U1 and U2 are applied.

The lower electrode 81 is divided into strip-formed segments, which are not electrically connected. OLED segments 40 are divided into the organic areas “b” and “y” which emit light in different colours. The upper electrode 80 comprises segments, which are applied offset from OLED segments by making contact between the upper electrode 80 and an adjacent strip of the lower electrode 81. The upper electrode 80 of the organic areas “y” thereby contacts the respective strip-formed segment of the lower electrode 81 arranged underneath in FIG. 6, whilst the upper electrode 80 of organic areas “b” contacts the respective strip-formed segment of the lower electrode 81 arranged on top in FIG. 5. This places the individual organic areas in series, where the polarity of the light-emitting organic areas “b” and “y” is respectively opposed under the condition that they have the same orientation in respect of the preferred charge transfer from the diodes to the substrate, the polarity being reversed for the voltages U1 and U2 respectively. Thus, when a voltage U1, U2 is applied, either the organic area “b” or the organic area “y” is supplied with a voltage in the forward, i.e. operating, direction, but the organic areas emitting light of a different colour are supplied in the reverse direction. If the potential is reversed, the respective other organic areas are correspondingly supplied with a voltage in the operating or reverse direction.

Square-wave voltage pulses may be used. Only the organic areas “b” will then light in the forward direction. The organic areas “y” will light in the reverse direction. Brightness and colour may be adjusted by varying the length and amplitude of the square-wave voltage pulses. By means of the arrangement, series circuits of light-emitting organic components are created so that the entire component will not fail if one light-emitting area fails.

In addition, the strip arrangement of electrode 81 ensures that the current will flow through another series circuit if there is an interruption to one of the series circuits. This means that only one organic area of the component will fail, whilst the remaining are continue to function.

In one embodiment, provision may be made for exchanging electrodes 80, 81, so that electrode 80 forms the lower electrode and electrode 81 forms the upper electrode.

The embodiment of a light-emitting component described with reference to FIG. 5 is useable as an independent principle, as well as a possible combination with the embodiments in FIGS. 1 to 4. In all the embodiments, structures with electrode arrangements are created, which are used to actuate organic areas, which are capable of emitting light in different colours. In the light-emitting components, overlapping areas of the electrodes provided are minimised or even avoided completely, with the exception of sections in which electrical contact is desired.

The characteristics of the invention disclosed in the above description, may be significant to implementation of the invention in its various embodiments, either individually or in any combination.

1. Light-emitting component with an electrode arrangement for the application of an electrical voltage to multiple organic areas, which form a light-emitting area and are distributed across a component surface and which each emit light when the electric current is applied, in which the multiple organic areas are arranged between a flat-formed electrode and a flat-formed counter-electrode, where the electrode consists of a part electrode and an additional part electrodes, which is electrically isolated from the part electrode and formed to interlock with it, where the electrode, and counter-electrode are formed so that they do not overlap each other outside the light-emitting area when looking towards the component surface.

2. Light-emitting component according to claim 1, wherein the counter-electrode has a part counter-electrode and an additional part counter-electrode, which is electrically isolated from the part counter-electrode and interlocks with it, and that the part electrode and the additional part electrode, and the part counter-electrode and the additional part counter-electrode, are arranged opposite each other when looking towards the component surface.

3. Light-emitting component according to claim 1, wherein the part electrode and the additional part electrode are each in contact with two different organic areas out of the multiple organic areas.

4. Light-emitting component according to claim 3, wherein the two different organic areas are formed so that they emit light of different colors.

5. Light-emitting component according to claim 1, wherein the part electrode and the additional part counter-electrode are formed so that they overlap, at least partially, within the light-emitting area when looking towards the component surface.

6. Light-emitting component according to claim 1, wherein the additional part-electrode and the part counter-electrode are each in contact with precisely one of the organic areas.

7. Light-emitting component according to claim 3, wherein the precisely one organic area emits light, which differs from the light, which is omitted by the two different organic areas.

8. Light-emitting component according to claim 1, wherein the electrode electrode sections of the part electrode and electrode sections of the additional part electrode are arranged offset to one another having a gap in between when looking towards the component surface.

9. Light-emitting component according to claim 2, wherein the counter-electrode, electrode sections of the part counter-electrode and electrode sections of the additional part counter-electrode are arranged offset to one another having a gap in between when looking towards the component surface.

10. Light-emitting component according to claim 1, wherein the electrode and/or the counter-electrode has strip-formed electrode sections.

11. Light-emitting component according to claim 1, wherein the electrode and/or the counter-electrode are each formed in a single layer.

12. Light-emitting component according to claim 1, wherein the electrode and/or the counter-electrode are distributed across multiple layers.

13. Light-emitting component according to claim 1, wherein the electrode and/or the counter-electrode within the light-emitting area are formed to substantially overlap the organic areas completely within the light-emitting area.

14. Light-emitting component according to claim 1, wherein the part electrode and the additional part electrode, and the part counter-electrode and the additional part counter-electrode interlock with each other in the form of a comb.

15. Light-emitting component according to claim 1, wherein the multiple organic areas have an aggregate white light emission spectrum.

16. Light-emitting component with an electrode arrangement for applying an electrical voltage to multiple organic areas, which are arranged between a flat-formed electrode and a flat-formed counter-electrode of the electrode arrangement and emit light when the electrical voltage is applied, where an arrangement of multiple series circuits is formed, in which:
the electrode is formed as multiple strip segments arranged adjacent to each other, and the counter-electrode is segmented;
the multiple organic areas are each connected to multiple strip segments of the electrodes; and
by the segmented counter-electrodes, each of the organic areas is connected to one adjacent strip segment, which is arranged adjacent to one of the multiple strip segments, so that one part of the multiple organic areas is connected to one adjacent strip segment on one side and another part of the organic areas is connected to an adjacent strip segment on an opposite side.
